(19) United States
(12) Patent Application Publication
(10) Pub. No.: US 2008/0303154 A1
(43) Pub. Date: Dec. 11, 2008

(54) Through-silicon via interconnection formed with a cap layer

(76) Inventors: Hon-Lin Huang, Hsinchu (TW); Boe Su, Chiayi (TW); Li-Hsin Tseng, Jhubei (TW); Chia-Jen Cheng, Banciao (TW); Hsiu-Mei Yu, Hsinchu (TW)

Correspondence Address: SLATER & MATSIL, L.L.P., 17950 PRESTON ROAD, SUITE 1000, DALLAS, TX, 75252, US

(21) Appl. No.: 11/811,660

(22) Filed: Jun. 11, 2007

(51) Int. Cl. H01L 23/528; H01L 21/4763

(52) U.S. Cl. 257/751; 438/643; 257/E23.151; 257/E21.495

(57) ABSTRACT

An integrated circuit structure and methods for forming the same are provided. The method includes providing a substrate; forming a through-silicon via (TSV) opening extending into the substrate; forming an under-bump metallurgy (UBM) in the TSV opening, wherein the UBM extends out of the TSV opening; filling the TSV opening with a metallic material; forming a patterned cap layer on the metallic material; and etching a portion of the UBM outside the TSV opening, wherein the patterned cap layer is used as a mask.

### TECHNICAL FIELD

This invention relates generally to integrated circuits, and more particularly to structures and manufacturing methods of through-silicon vias.

### BACKGROUND

Since the invention of integrated circuits, the semiconductor industry has experienced continuous rapid growth due to constant improvements in the integration density of various electronic components (i.e., transistors, diodes, resistors, capacitors, etc.). For the most part, this improvement in integration density has come from repeated reductions in minimum feature size, allowing more components to be integrated into a given chip area.

These integration improvements are essentially two-dimensional (2D) in nature, in that the volume occupied by the integrated components is essentially on the surface of the semiconductor wafer. Although dramatic improvements in lithography have resulted in considerable improvements in 2D integrated circuit formation, there are physical limitations to the density that can be achieved in two dimensions. One of these limitations is the minimum size needed to make these components. Also, when more devices are put into one chip, more complex designs are required.

An additional limitation comes from the significant increase in the number and length of interconnections between devices as the number of devices increases. When the number and length of interconnections increase, both circuit RC delay and power consumption increase.

Among the efforts for resolving the above-discussed limitations, three-dimensional integrated circuit (3DIC) and stacked dies are commonly used. Through-silicon vias (TSV) are often used in 3DIC and stacked dies for connecting dies. In this case, TSVs are often used to connect the integrated circuits on a die to the backside of the die. In addition, TSVs are also used to provide a short grounding path to connect the ground in the integrated circuits to the backside of the die, which is typically covered by a grounded aluminum film.

FIGS. 1 through 2B illustrate a conventional method for forming TSVs. Referring to FIG. 1, silicon substrate 2 is provided, on which integrated circuits (not shown) are formed. Dielectric layers 6, in which metal lines and vias (not shown) are formed, are then formed layer-by-layer over silicon substrate 2. Pad 8 is formed on the top of dielectric layers 6 and is connected to the integrated circuits. Silicon substrate 2 and the overlying dielectric layers 6 are then etched, forming an opening. A glue layer (not shown) is formed lining the sidewalls and the bottom of the opening. Thin seed layer 10, commonly referred to as under-bump metallurgy (UBM) 10, is then formed on the glue layer. UBM 10 is typically formed of copper. The remaining portion of the opening is then filled using copper, forming TSV 12. TSV 12 is connected to the integrated circuits through pad 8. Also, post-passivation interconnect (PPI) lines 14, which are also formed of copper, are formed simultaneously with the filling of the opening.

Referring to FIGS. 2A and 2B, UBM 10 needs to be patterned, otherwise, TSV 12 and PPI lines 14 will be shorted by UBM 10. An etching is thus performed to remove the portions of UBM 10 between TSV 12 and PPI lines 14. Since TSV 12 and PPI lines 14 include a same material (copper) as UBM 10, the etching process is hard to control. If an under-etch occurs, as is shown in FIG. 2A, residue 15 is left between PPI lines 14, and/or between TSV12 and PPI lines 14. Conversely, if an over-etch occurs, as is shown in FIG. 2B, TSV 12 may be damaged, and the connection between TSV 12 and pad 8 may be broken.

The conventional TSV formation process also suffers from other drawbacks. Referring to FIG. 3, after the formation of TSV 12, a cleaning step is performed to remove the native copper oxide formed on the top surface of TSV 12. A solder mask layer 18 is blanket formed, and then patterned, exposing bonding pad 20. Solder mask layer 18 typically includes an organic, and non-conductive material. The extra steps to clean the top surface of TSV 12 and to form and pattern solder mask layer 18 involve extra manufacturing cost. A new TSV structure and methods for forming the same are thus needed.

### SUMMARY OF THE INVENTION

In accordance with one aspect of the present invention, a method for forming an integrated circuit structure includes providing a substrate; forming a through-silicon via (TSV) opening extending into the substrate; forming an under-bump metallurgy (UBM) in the TSV opening, wherein the UBM extends out of the TSV opening; filling the TSV opening with a metallic material; forming a patterned cap layer on the metallic material; and etching a portion of the UBM outside the TSV opening, wherein the patterned cap layer is used as a mask.

In accordance with another aspect of the present invention, a method of forming an integrated circuit structure includes providing a wafer comprising a pad on a top surface of the wafer; forming a through-silicon via (TSV) opening extending into the wafer, wherein the TSV opening is adjacent to the pad; blanket forming a diffusion barrier layer over the wafer, wherein the diffusion barrier layer extends into the TSV opening; blanket forming a copper seed layer on the diffusion barrier layer; forming and patterning a mask layer over portions of the copper seed layer exposed through the mask layer, wherein the pad, the TSV opening, and a region therebetween are exposed through the mask layer; selectively forming a copper layer on the copper seed layer, wherein the copper layer fills the TSV opening and extends over the pad; selectively forming a cap layer on the copper layer; removing the mask layer, wherein portions of the copper seed layer and the diffusion barrier layer underlying the mask layer are exposed; etching exposed portions of the copper seed layer using the cap layer as a mask; and etching exposed portions of the barrier layer using the cap layer as a mask.

In accordance with yet another aspect of the present invention, an integrated circuit structure includes a substrate; a through-silicon via (TSV) extending into the substrate; a metal feature on the TSV, wherein the metal feature and the TSV comprise a same material and form a continuous region; and a cap layer on the metal feature, wherein the cap layer and the metal feature are co-terminus.

In accordance with yet another aspect of the present invention, an integrated circuit structure includes a substrate; a through-silicon via (TSV) extending into the substrate; a pad over the substrate and adjacent the TSV; a metal feature extending from over the TSV to over the pad, wherein the metal feature and the TSV comprise a same material and form a continuous region, and wherein the metal feature is electrically connected to the TSV and the pad; and a cap layer over and physically contacting the metal feature, wherein the cap layer and the metal feature are co-terminus.

The advantageous features of the present invention includes reduced process steps, and hence reducing manufacturing cost, and improving reliability of the resulting integrated circuits.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 3 illustrate a conventional process for forming a through-silicon via; and

FIGS. 4 through 12 are cross-sectional views of intermediate stages in the manufacturing of an embodiment of the present invention, wherein a cap layer is formed over TSV before the etching of a seed layer.

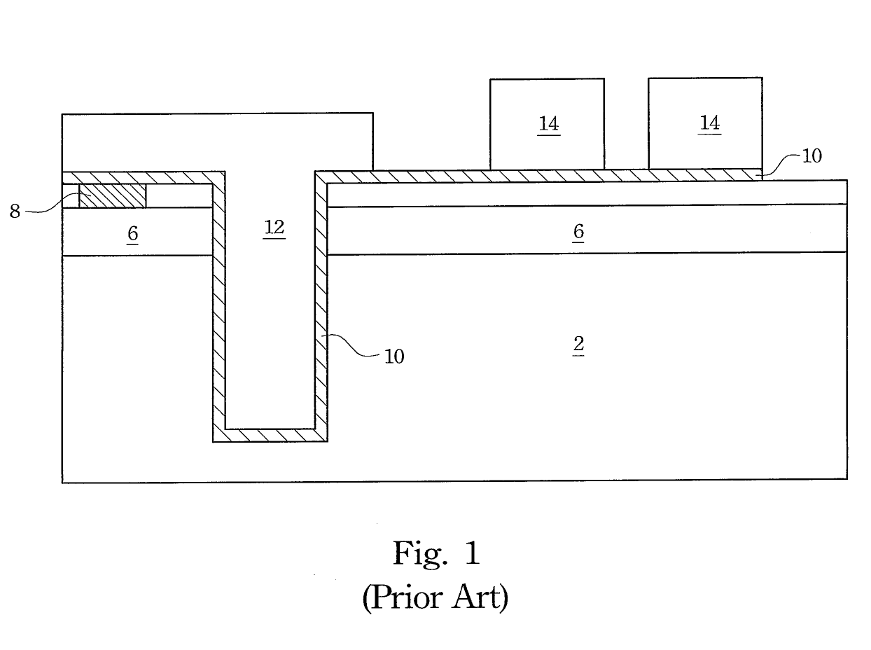

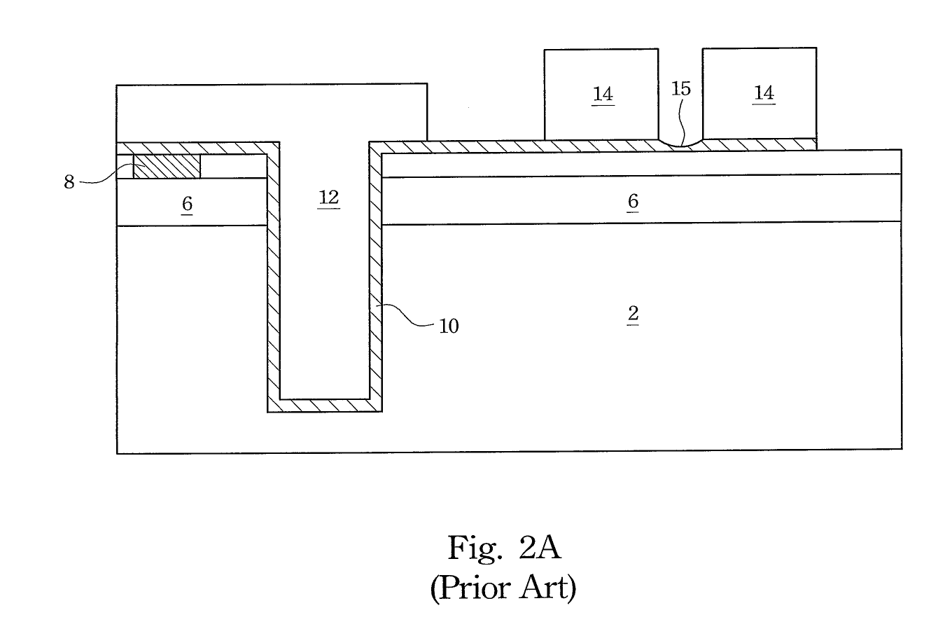

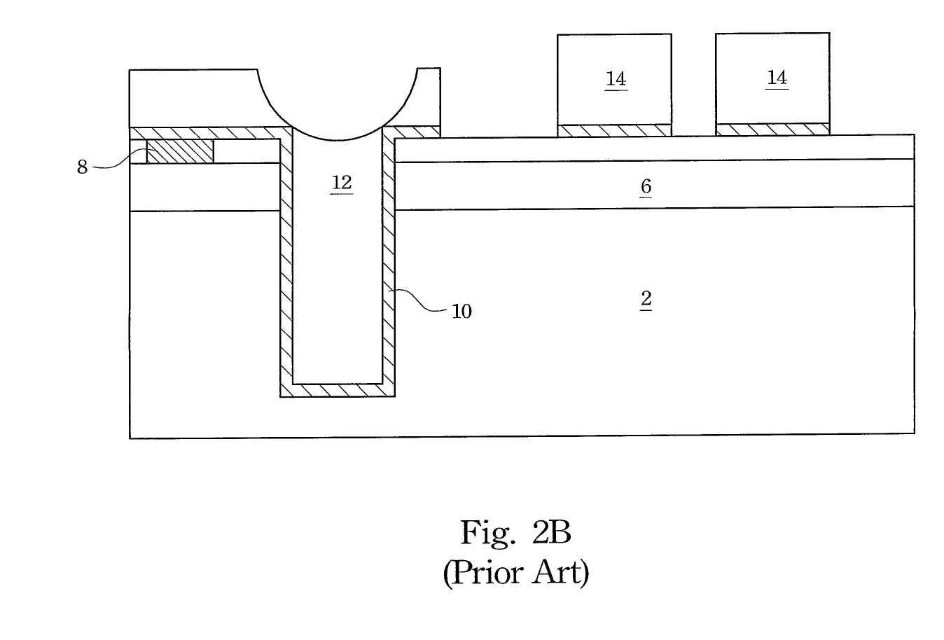

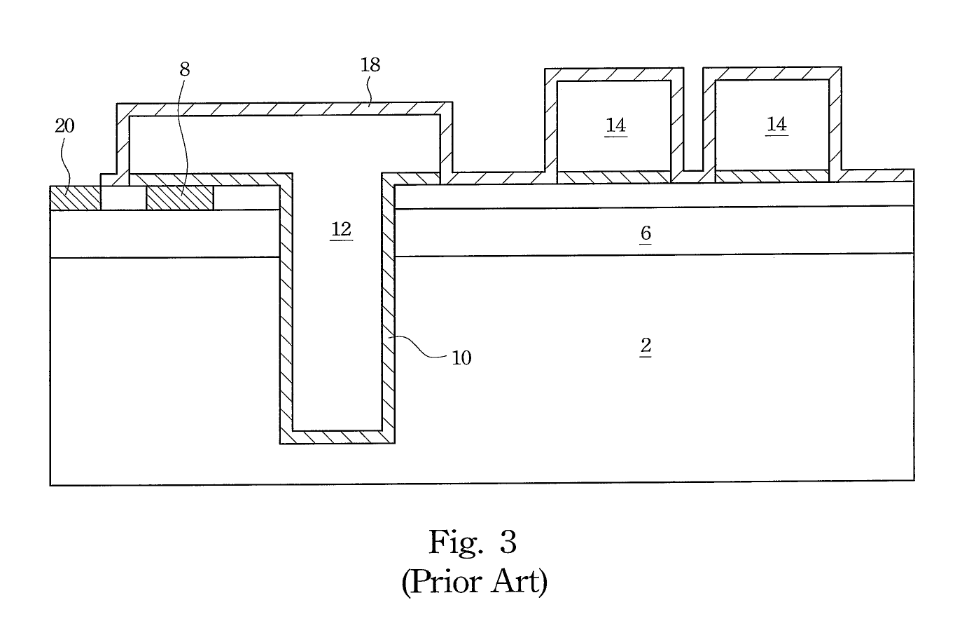

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method for forming through-silicon vias is provided. The intermediate stages of manufacturing a preferred embodiment of the present invention are illustrated. Throughout the various views and illustrative embodiments of the present invention, like reference numbers are used to designate like elements.

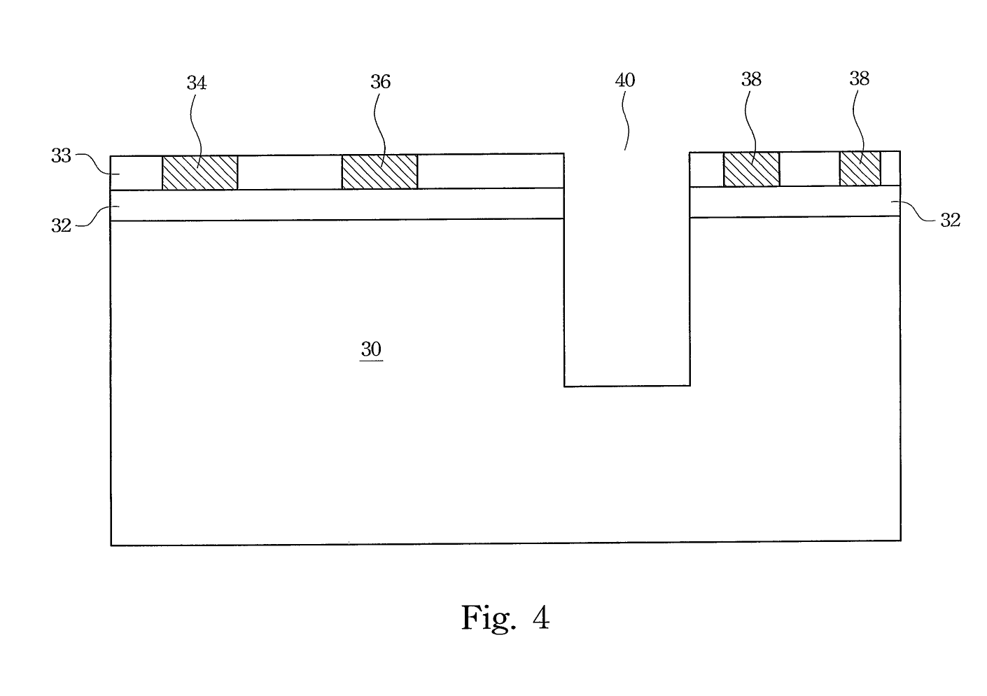

Referring to FIG. 4, a wafer including base material 30 is provided. Base material 30 preferably includes a semiconductor substrate, such as bulk silicon substrate. Other semiconductor materials including group III, group IV and group V elements may also be used. Alternatively, base material 30 may include non-conductive layers. Integrated circuits and overlying metallization layers, which are symbolized by layer 32, are formed on the surface of base material 30. Passivation layer 33 is formed, in which pads 34, 36 and 38 are formed. Preferably, pads 34, 36 and 38 are connected to the integrated circuits in the wafer.

FIG. 4 also illustrates the formation of through-silicon via opening 40, which extends into base material 30. In an embodiment, through-silicon via opening 40 is formed by etching. Alternatively, laser drilling may be used.

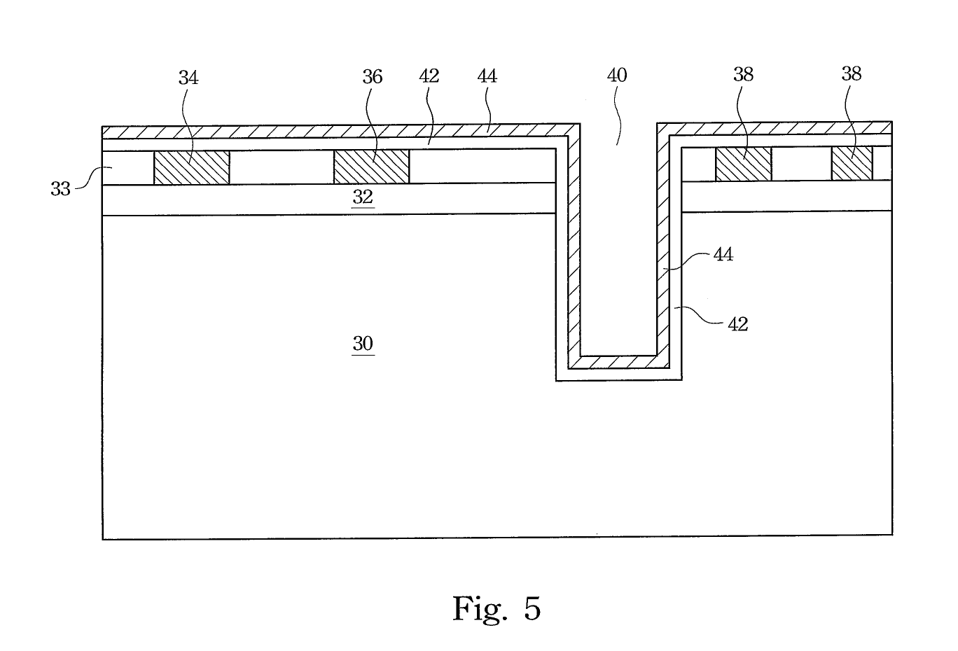

Referring to FIG. 5, diffusion barrier layer 42, also referred to as a glue layer, is blanket formed, covering the sidewalls and the bottom of opening 40. Diffusion barrier layer 42 may include commonly used barrier materials such as titanium, titanium nitride, tantalum, tantalum nitride, and combinations thereof, and can be formed using physical vapor deposition, sputtering, and the like.

A thin seed layer 44, also referred to as an under-bump metallurgy (UBM), is blanket formed on diffusion barrier layer 42. The materials of seed layer 44 include copper or copper alloys, and metals such as silver, gold, aluminum, and combinations thereof may also be included. In an embodiment, seed layer 44 is formed of sputtering. In other embodiments, other commonly used methods such as physical vapor deposition or electroless plating may be used. Thin seed layer 44 preferably has a thickness of less than about 2 μm.

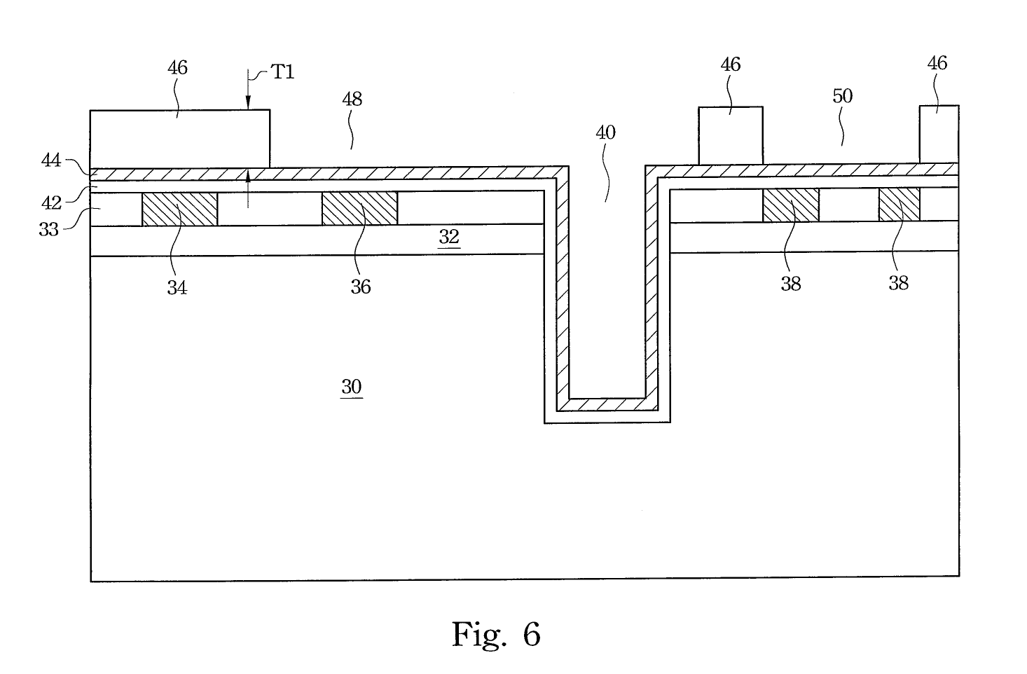

Referring to FIG. 6, mask 46 is formed on the previously formed structure. In the preferred embodiment, mask 46 comprises an organic material such as Ajinimoto buildup film (ABF). However, other materials such as Prepreg and resin coated copper (RCC) can also be used. In the case mask 46 is formed of ABF, the ABF film is first laminated on the structure shown in FIG. 5. Heat and pressure are then applied to the laminated film to soften it so that a flat top surface is formed. In the resulting structure, mask 46 has a thickness T1 of greater than about 5 μm, and more preferably between about 10 μm and about 100 μm. Alternatively, mask 46 is a photo resist, which may either be a positive photo resist or an negative photo resist.

Mask 46 is then patterned. In an exemplary embodiment, the resulting TSV needs to be connected to the integrated circuits in layer 32 through pad 36. Accordingly, opening 48 is formed in mask 46, exposing portions of diffusion barrier layer 42 and seed layer 44 over pad 36, opening 40 and the region therebetween. Also, pads 38 are preferably interconnected by a post-passivation interconnect (PPI) line. Therefore, trench 50 is formed in mask 46, exposing portions of diffusion barrier layer 42 and seed layer 44 over pads 38 and the region therebetween.

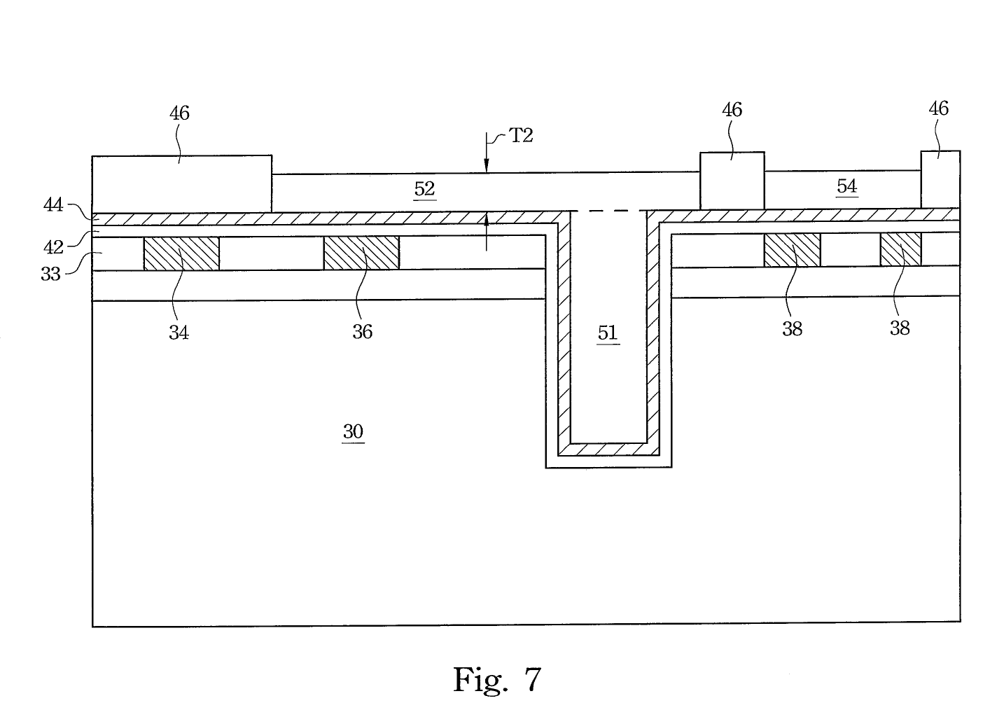

In FIG. 7, opening 40 is selectively filled with a metallic material, forming TSV 51 in opening 40. In the preferred embodiment, the filling material includes copper or copper alloys. Other metals, such as aluminum, silver, gold, and combinations thereof, may also be used. The formation methods may include sputtering, printing, electro plating, electroless plating, and commonly used chemical vapor deposition (CVD) methods.

At the time opening 40 is filled with the metallic material, the same metallic material is also formed in openings 48 and 50 (refer to FIG. 6), forming metal lines 52 and 54, respectively. Throughout the description, metal lines 52 and 54 are referred to as post-passivation interconnect (PPI) lines 52 and 54, respectively. Preferably, PPI lines 52 and 54 have a thickness T2 of less than about 30 μm, and more preferably between about 2 μm and about 25 μm.

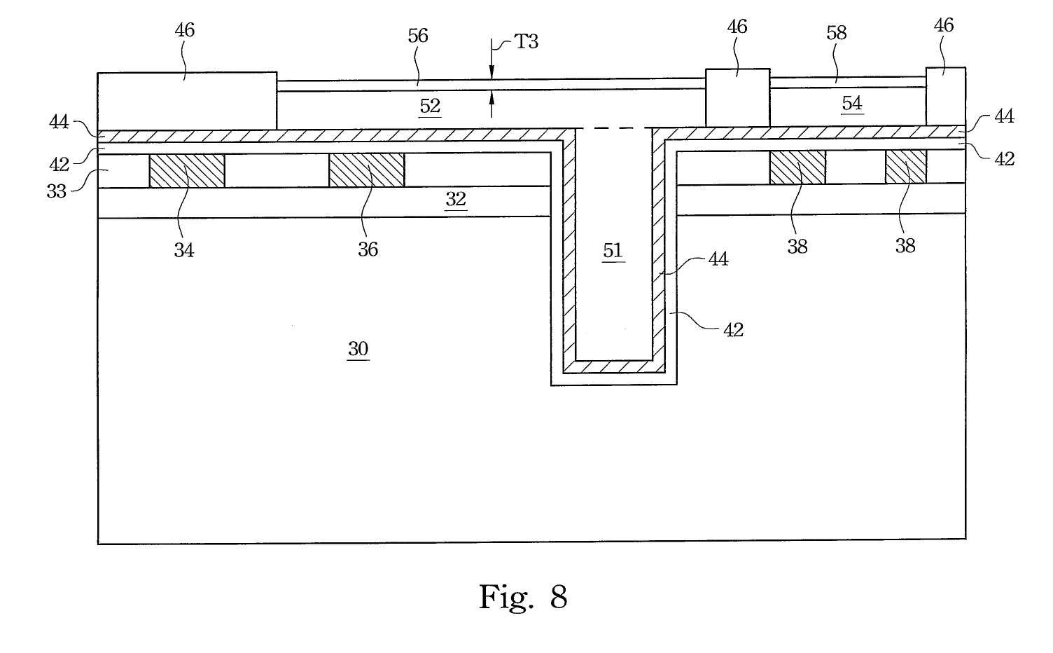

Next, as is shown in FIG. 8, cap layers 56 and 58 are selectively formed over PPI lines 52 and 54, respectively. Cap layers 56 and 58 preferably have different etching characteristics from UBM 44 and diffusion barrier layer 42, so that in the subsequent steps for etching UBM 44 and diffusion barrier layer 42, cap layers 56 and 58 may protect the underlying PPI lines 52 and 54. In the preferred embodiment, cap layers 56 and 58 include nickel. In alternative embodiments, cap layers 56 and 58 may include a solder material, such as eutectic solder materials or high-lead solder materials, which may include tin and lead. In yet other embodiments, cap layers 56 and 58 are formed of a lead-free solder material such as tin-silver, tin-silver-copper, and the like. In yet other embodiments, cap layers 56 and 58 may include dielectric materials such as silicon-nitride, silicon-oxide, and the like, or organic materials such as polymer, and the like.

Cap layers 56 and 58 preferably have thickness T3 of less than about 20 μm, and more preferably between about 0.5 μm and about 5 μm. The formation methods include plating, electroless plating, sputtering, chemical vapor deposition methods, and the like. It is noted that cap layers 56 and 58 are co-terminus with the respective underlying PPI lines 52 and 54. Since cap layers 56 and 58 are formed immediately after the formation of TSV 51 and PPI lines 52 and 54, it is not necessary to perform a cleaning step, which was conventionally performed before a solder mask (not shown) is formed to protect PPI lines 52 and 54. In the preferred embodiment, cap layers 56 and 58 are selectively formed on exposed metal features 52 and 54. In other embodiment, a blanket cap layer is formed, and then patterned to form cap layers 56 and 58.

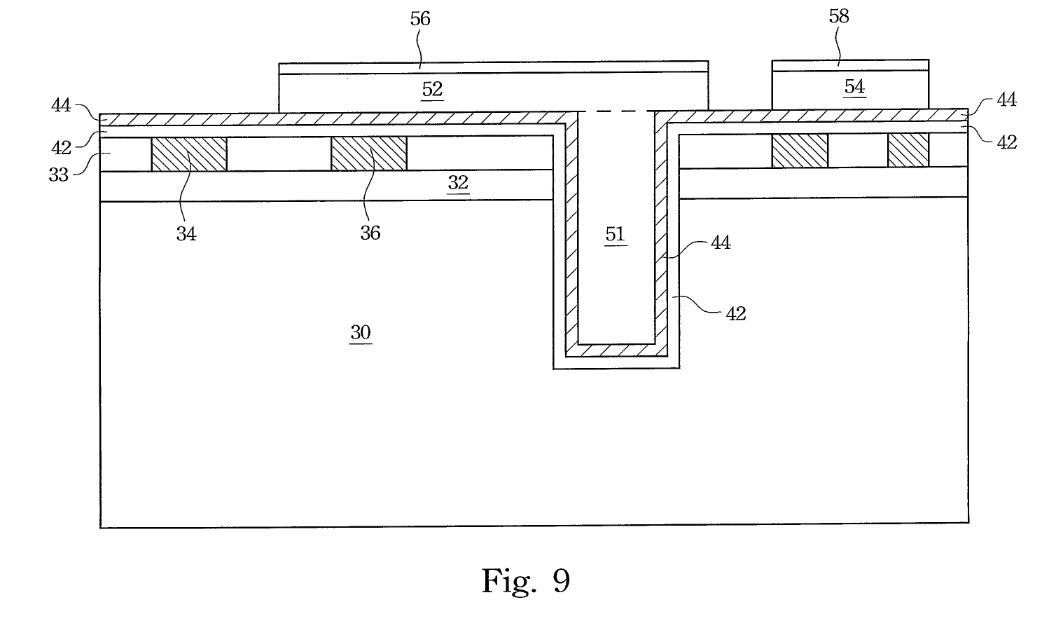

In FIG. 9, mask 46 is removed. In the case mask 46 is a dry film, it may be removed by an alkaline solution. If mask 46 is formed of photo resist, it may be removed by acetone, n-methyl pyrrolidone (NMP), dimethyl sulfoxide (DMSO), aminoethoxy ethanol, and the like. As a result, the portions of UBM 44 underlying mask 46 are exposed.

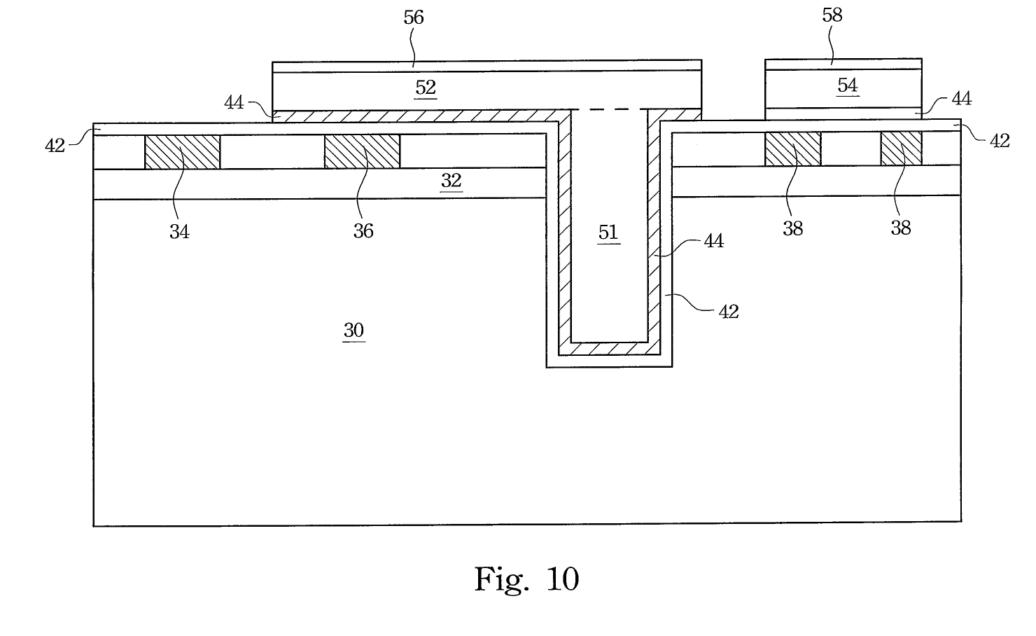

Referring to FIG. 10, the exposed portions of UBM 44 are removed. In an exemplary embodiment, the removal of UBM 44 is performed by an isotropic wet etching in an ammonia-based acid. Cap layers 56 and 58 are resistive to the chemicals used in the removal of UBM 44. Accordingly, PPI lines 52 and 54 are protected from the etching.

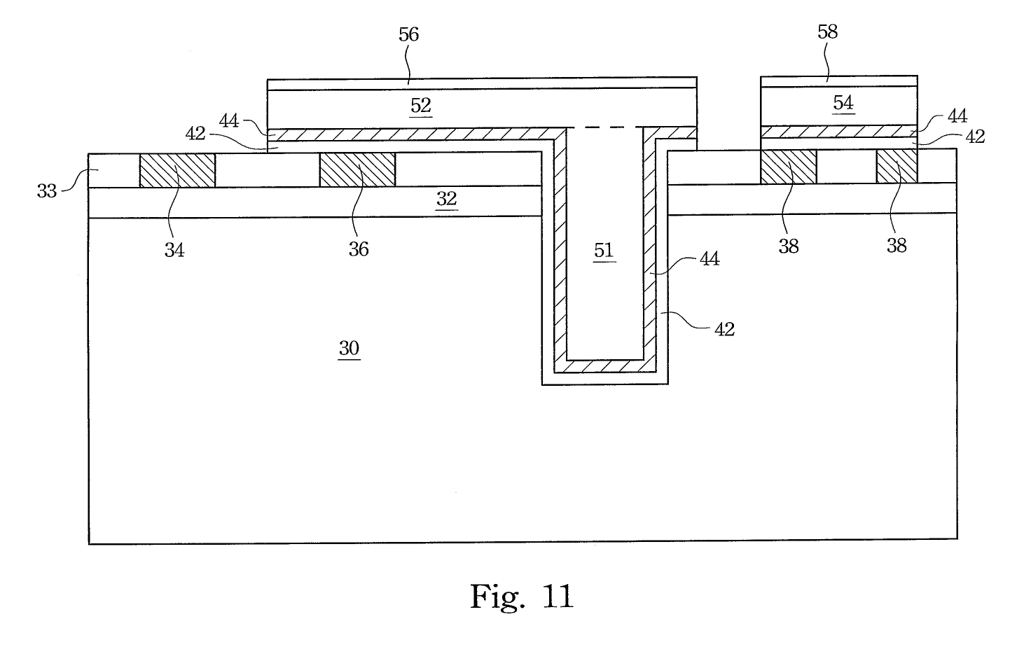

FIG. 11 illustrates a pad opening step, in which the exposed portions of diffusion barrier layer 42 are removed. As a result, pad 34, which may be used in the subsequent bonding process to connect the integrated circuits in the respective chip to external features, is exposed. In an exemplary embodiment, the exposed portion of the diffusion barrier layer 42 is removed using a fluorine-based etching gas. Preferably, the etching is anisotropic.

In the steps of UBM etching and pad opening, cap layers 56 and 58 act as a mask layer, protecting underlying metal lines 52 and 54 from being attacked by the chemicals used in the removal of UBM 44 and diffusion barrier layer 42. Accordingly, the control of the removal of UBM 44 becomes less critical, and the adverse under-etching or over-etching is less likely to cause a shorting between PPI lines 52 and 54, or the damage of PPI lines 52 and 54, as well as TSV 51.

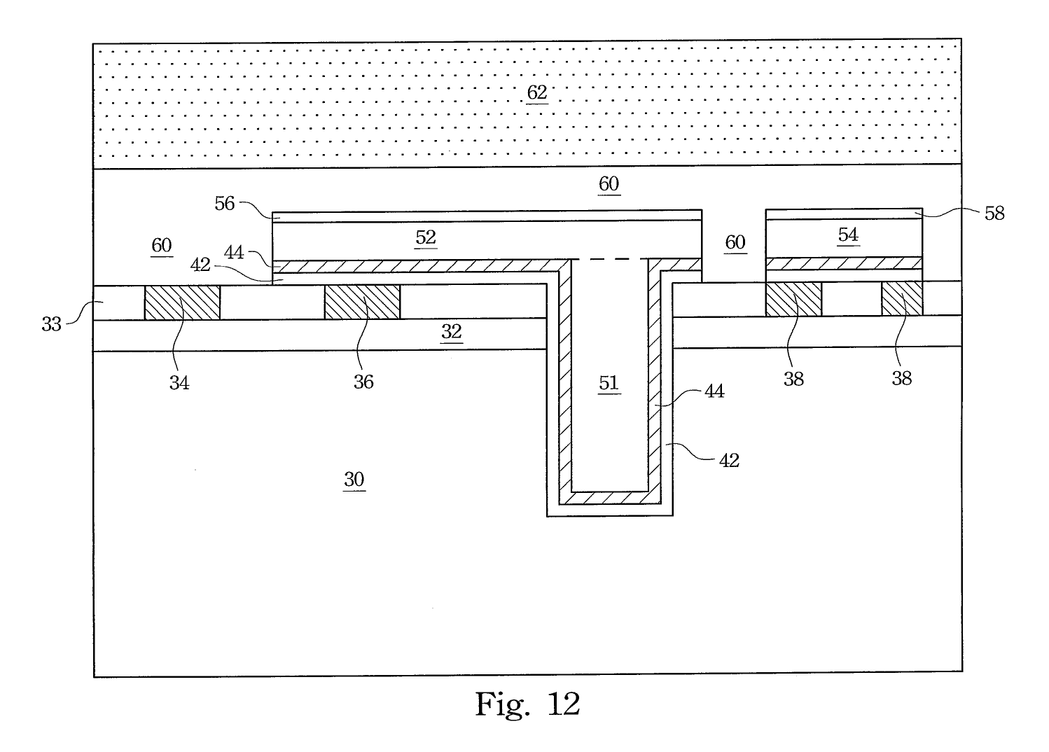

In subsequent steps, as is shown in FIG. 12, glass wafer 62 may be mounted on the top surface of the structure formed in the previously discussed steps through ultra-violet (UV) glue 60. A wafer grinding is then performed to thin the back surface of the base material 30, until TSV 51 is exposed. Glass wafer 62 is then de-mounted by exposing UV glue 60 to an UV light, causing it to lose its adhesive property.

By using the embodiments of the present invention, it is no longer necessary to apply a solder mask for the purpose of protecting the surfaces of PPI lines 52 and 54, since cap layers 56 and 58 act as protection layers. In addition, cap layers 56 and 58 act as a mask in the removal of UBM 44, and hence the removal of UBM 44 is easier to control. Further, the manufacturing cost is reduced since the conventional steps of cleaning the surfaces of PPI lines 52 and 54, forming a solder mask, and patterning the solder mask are now replaced by a single step of forming cap layers 56 and 58.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming an integrated circuit structure, the method comprising:
providing a substrate;
forming a through-silicon via (TSV) opening extending into the substrate;
forming an under-bump metallurgy (UBM) in the TSV opening, wherein the UBM extends out of the TSV opening;
filling the TSV opening with a metallic material;
forming a patterned cap layer on the metallic material; and
etching a portion of the UBM outside the TSV opening, wherein the patterned cap layer is used as a mask.

2. The method of claim 1, wherein the patterned cap layer is co-terminus with the metallic material.

3. The method of claim 1, wherein the UBM and the metallic material comprise copper, and wherein the patterned cap layer comprises nickel.

4. The method of claim 1 further comprising:
before the step of forming the UBM, forming a diffusion barrier layer in the TSV opening, wherein the diffusion barrier layer extends outside of the TSV opening; and
removing a portion of the diffusion barrier layer outside of the TSV using the patterned cap layer as the mask.

5. The method of claim 1, wherein the UBM is formed by sputtering, and wherein the metallic material is formed using plating.

6. The method of claim 1, wherein the metallic material extends beyond edges of the TSV opening and over a pad, and wherein the pad and the TSV are electrically interconnected through the UBM.

7. The method of claim 1, wherein the UBM extends over a first pad and a second pad, and wherein the method further comprises:
forming a post-passivation interconnect (PPI) line over and electrically connecting the first pad and the second pad, wherein the PPI line is formed simultaneously with the step of filling the metallic material into the TSV opening; and
forming an additional cap layer on the PPI line, wherein the additional cap layer is formed simultaneously with the step of forming the patterned cap layer.

8. The method of claim 7, wherein the additional cap layer is co-terminus with the PPI line.

9. A method of forming an integrated circuit structure, the method comprising:
providing a wafer comprising a pad on a top surface of the wafer;
forming a through-silicon via (TSV) opening extending into the wafer, wherein the TSV opening is adjacent to the pad;
blanket forming a diffusion barrier layer over the wafer, wherein the diffusion barrier layer extends into the TSV opening;
blanket forming a copper seed layer on the diffusion barrier layer;
forming and patterning a mask layer over portions of the copper seed layer exposed through the mask layer, wherein the pad, the TSV opening, and a region therebetween are exposed through the mask layer;
selectively forming a copper layer on the copper seed layer, wherein the copper layer fills the TSV opening and extends over the pad;
selectively forming a cap layer on the copper layer;
removing the mask layer, wherein portions of the copper seed layer and the diffusion barrier layer underlying the mask layer are exposed;
etching exposed portions of the copper seed layer using the cap layer as a mask; and
etching exposed portions of the barrier layer using the cap layer as a mask.

10. The method of claim 9 further comprising:
applying an ultra-violet glue on the cap layer, wherein the ultra-violet glue physically contacts the cap layer; and
mounting a glass wafer on the ultra-violet glue.

11. The method of claim 9, wherein the cap layer is co-terminus with the copper layer after the step of removing the mask layer.

12. The method of claim 9, wherein the cap layer comprises nickel.

13. The method of claim 9, wherein the copper seed layer is formed using sputtering, and wherein the copper layer is formed using plating.

14. The method of claim 9, wherein the copper seed layer extends over a first pad and a second pad, and wherein the method further comprises:
forming a post passivation interconnect (PPI) line over and electrically connecting the first pad and the second pad, wherein the PPI line is formed simultaneously with the step of selectively forming the copper layer; and
forming an additional cap layer over the PPI line, wherein the additional cap layer is formed simultaneously with the step of forming the cap layer.

15. The method of claim 14, wherein the additional cap layer is co-terminus with the PPI line.

16. An integrated circuit structure comprising:
a substrate;
a through-silicon via (TSV) extending into the substrate;
a metal feature on the TSV, wherein the metal feature and the TSV comprise a same material and form a continuous region; and
a cap layer on the metal feature, wherein the cap layer and the metal feature are co-terminus.

17. The integrated circuit structure of claim 16, wherein the cap layer comprises nickel, and wherein the metal feature and the TSV comprises copper.

18. The integrated circuit structure of claim 16, wherein the cap layer comprises a dielectric material.

19. The integrated circuit structure of claim 16 further comprising a pad over the substrate and adjacent the TSV, wherein the metal feature extends over and electrically connecting the TSV to the pad.

20. The integrated circuit structure of claim 19 further comprising a diffusion barrier layer between the TSV and the substrate, wherein the diffusion barrier layer is co-terminus with the cap layer.

21. The integrated circuit structure of claim 16 further comprising:
a first pad and a second pad over the substrate;
a post-passivation interconnect (PPI) line over and electrically connecting the first pad and the second pad, wherein the PPI line and the TSV comprise a same material; and
an additional cap layer over the PPI line, wherein the additional cap layer and the cap layer comprise a same material.

22. The integrated circuit structure of claim 21, wherein the additional cap layer is co-terminus with the PPI line.

23. The integrated circuit structure of claim 16 further comprising:
a seed layer underlying the metal feature and the TSV; and
a diffusion barrier layer underlying the seed layer, wherein the seed layer and the diffusion barrier layer are co-terminus with the cap layer.

24. An integrated circuit structure comprising:
a substrate;
a through-silicon via (TSV) extending into the substrate;
a pad over the substrate and adjacent the TSV;
a metal feature extending from over the TSV to over the pad, wherein the metal feature and the TSV comprise a same material and form a continuous region, and wherein the metal feature is electrically connected to the TSV and the pad; and
a cap layer over and physically contacting the metal feature, wherein the cap layer and the metal feature are co-terminus.

25. The integrated circuit structure of claim 24 further comprising:
a seed layer underlying the metal feature and the TSV; and
a diffusion barrier layer underlying the seed layer.

26. The integrated circuit structure of claim 25, wherein the seed layer and the diffusion barrier layer extend between the metal feature and the pad.

27. The integrated circuit structure of claim 25, wherein the seed layer and the diffusion barrier layer are substantially co-terminus with the metal feature.

28. The integrated circuit structure of claim 24, wherein the cap layer comprises nickel, and wherein the TSV and the metal feature comprise copper.

29. The integrated circuit structure of claim 24, wherein the cap layer comprises a dielectric material.

30. The integrated circuit structure of claim 24 further comprising:
a first pad and a second pad over the substrate;
a post-passivation interconnect (PPI) line over and electrically connecting the first pad and the second pad, wherein the PPI line and the TSV comprise a same material; and
an additional cap layer over the PPI line, wherein the additional cap layer and the cap layer comprise a same material.
